(19) United States
(12) Patent Application Publication
(10) Pub. No.: US 2017/0186607 A1
(43) Pub. Date: Jun. 29, 2017

(54) METHOD OF FORMING A SEMICONDUCTOR DEVICE

(71) Applicant: UNITED MICROELECTRONICS CORP., Hsin-Chu City (TW)

(72) Inventors: Yi-Ting Kuo, Chiayi County (TW); Shih-Jung Tu, Kaohsiung City (TW); Chun-Liang Chen, Tainan City (TW); Po-Lun Cheng, Kaohsiung City (TW)

(21) Appl. No.: 14/981,854

(22) Filed: Dec. 28, 2015

(51) Int. Cl. H01L 21/02; H01L 29/66; H01L 21/3205

(52) U.S. Cl. CPC H01L 21/02332; H01L 21/02164; H01L 21/02181; H01L 21/02192; H01L 21/02183; H01L 21/02189; H01L 21/02178; H01L 21/02186; H01L 21/02271; H01L 21/02236; H01L 21/0234; H01L 21/02318; H01L 21/32055; H01L 21/32051; H01L 29/66477

(57) ABSTRACT

The method of forming a semiconductor device is provided. A substrate having an exposed oxide layer is provided. A nitridation process is performed for the oxide layer. After the nitridation process, a plasma treatment containing an inert gas is performed for the oxide layer. A conductive layer is formed on the oxide layer.

### BACKGROUND OF THE INVENTION

1. Field of the Invention

The present invention relates to a method of forming a semiconductor device, and more particularly, to a method of forming a semiconductor device with a nitridation process for an oxide layer.

2. Description of the Prior Art

Micro-processor systems comprised of integrated circuits (IC) are ubiquitous devices in modern society, being utilized in such diverse fields as automatic control electronics, mobile communication devices and personal computers. With the development of technology and the increasingly imaginative applications of electrical products, IC devices are becoming smaller, more delicate and more diversified.

Along with the miniaturization of the IC device, however, manufacturers have encountered problems related to IC fabrication methods. Silicon oxide is the most popular material for gate dielectric, but has therein pin holes easily causing electrical issues like direct tunneling current and is therefore difficult to be made into a thin gate dielectric layer. A gate dielectric layer formed as a silicon oxide layer can be doped with nitrogen to reduce current leakage and improve the device reliability. However, the nitrogen atoms easily diffuse to the interface between the substrate and the gate dielectric layer and reduce the performance and reliability of the device.

Accordingly, there is still a need to provide a novel manufacturing method to avoid the problem of nitrogen diffusion

### SUMMARY OF THE INVENTION

The present invention therefore provides a method to avoid nitrogen diffusion into the substrate.

According to one embodiment of the present invention, a method of forming a semiconductor device is provided. A substrate having an exposed oxide layer is provided. A nitridation process is performed for the oxide layer. After the nitridation process, a plasma treatment containing an inert gas is performed for the oxide layer. A conductive layer is formed on the oxide layer.

According to another embodiment of the present invention a method of forming a semiconductor device is provided. A substrate is provided, followed by forming a first oxide layer on the substrate. After forming the first oxide layer, a plasma treatment containing an inert gas is performed. After the plasma treatment, a second oxide layer is formed on the first oxide layer. After forming the first oxide layer, a nitridation process is performed. A conductive layer is formed on the oxide layer.

The method of forming a semiconductor device can solve the problem of nitrogen penetrating from an oxide layer into the under substrate by utilizes a plasma treatment with inert gas. Consequently, the device performance can be upgraded.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 illustrate schematic diagrams of the method of forming a semiconductor device according to one embodiment of the present invention.

FIG. 6 to FIG. 10 illustrate schematic diagrams of the method of forming a semiconductor device according to another embodiment of the present invention.

### DETAILED DESCRIPTION

To provide a better understanding of the present invention, preferred embodiments will be described in detail. The preferred embodiments of the present invention are illustrated in the accompanying drawings with numbered elements.

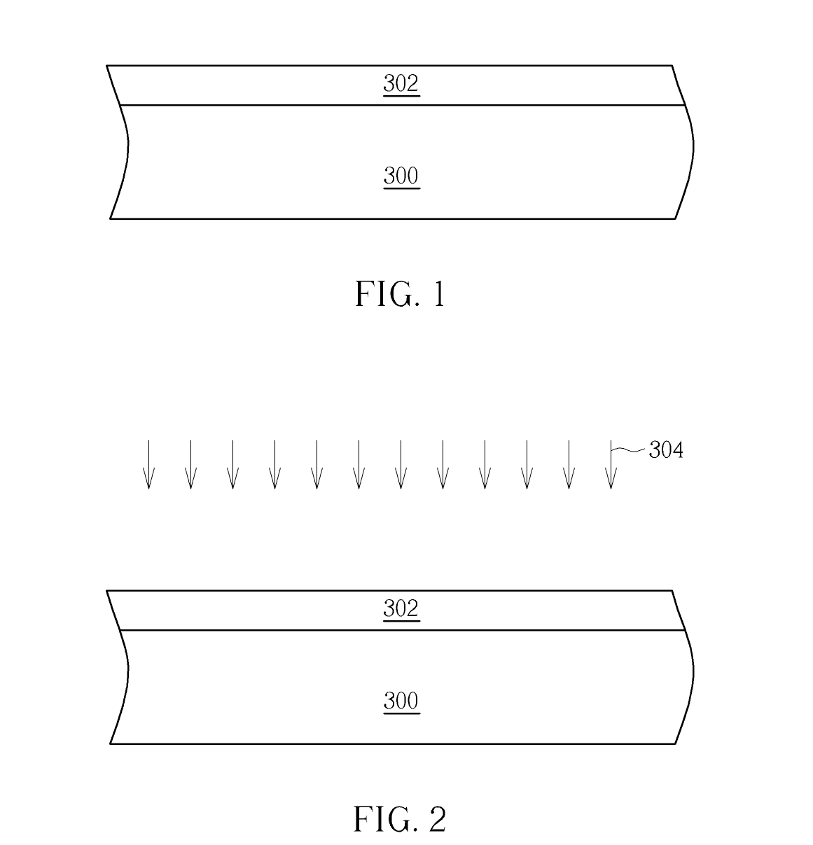

Please refer to FIG. 1 to FIG. 5, which illustrate schematic diagrams of the method of forming a semiconductor device according to one embodiment of the present invention. As shown in FIG. 1, a substrate 300 with an exposed oxide layer 302 is provided. The substrate 300 is provided to serve as a base for forming devices, components, or circuits. The substrate 300 is preferably composed of a silicon containing material. Silicon containing materials include, but are not limited to, Si, single crystal Si, polycrystalline Si, SiGe, single crystal silicon germanium, polycrystalline silicon germanium, or silicon doped with carbon, amorphous Si and combinations and multi-layered materials thereof. The substrate 300 may also be composed of other semiconductor materials, such as germanium, and compound semiconductor substrates, such as type III/V semiconductor substrates, e.g., GaAs. Although the substrate 300 is depicted as a bulk semiconductor substrate, the arrangement of a semiconductor on an insulator substrate, such as silicon-on-insulator (SOI) substrates, are also suitable for the substrate 300. The oxide layer 302 is formed on the substrate 300, preferably by a thermal oxidation process and thus contains SiO₂. In another embodiment, the oxide layer 302 may be formed by an in-situ steam generation (ISSG) oxidation process, a chemical vapor deposition (CVD) process or a decoupled plasma oxidation process. The oxide layer is less than 2 nm in thickness. In one embodiment, the thickness of the oxide layer 302 may range from 1.68 nm to 1.76 nm.

As shown in FIG. 2, a nitridation process 304 is performed for the exposed oxide layer 302. The nitridation process may utilize decoupled-plasma nitridation, remote plasma nitridation, or NH₃ thermal nitridation. The decoupled-plasma nitridation process may be a chamber decoupled-plasma nitridation process, a remote decoupled-plasma nitridation process, or a NH₃ thermal decoupled-plasma nitridation process.

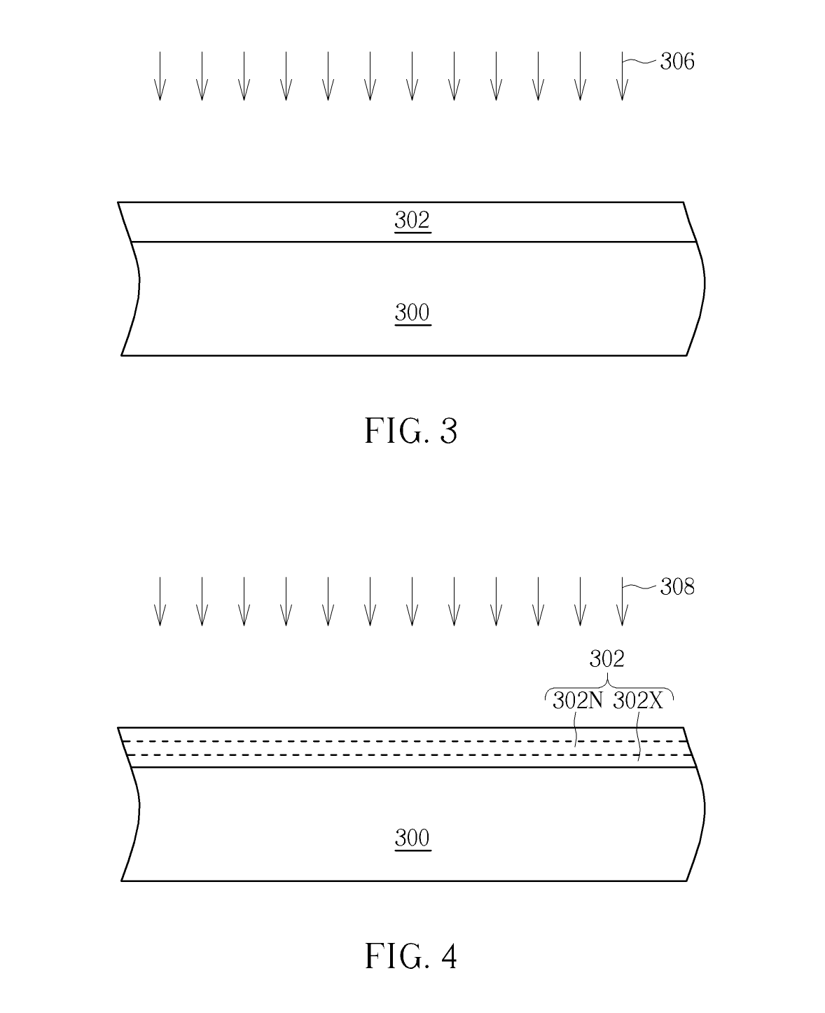

As shown in FIG. 3, after the nitridation process 304, a plasma treatment 306 is performed for the oxide layer 302. In one embodiment, the plasma treatment 306 includes supplying an inert gas such as xenon (Xe), krypton (Kr), radium (Ra), or combinations thereof. When nitridation process 304 is a DPN process, the plasma treatment 306 and the nitridation process can be performed in the same chamber and when supplying the inert gas, nitrogen can still be supplied. However, it is preferred that during the plasma treatment 306, only the inert gas is supplied into the chamber, and more preferably, only one kind of inert gas is supplied, so as to avoid the disturbance form nitrogen. In one embodiment, a power of the DPN nitridation process 304 is substantially less than a power of the plasma treatment 306. A gas flow rate of the nitride utilized in the nitridation process 304 is substantially less than a gas flow rate of the inert gas utilized in the plasma treatment 306. In one embodiment, the sequence of nitridation process 304 and the plasma treatment 306 can be reversed.

As shown in FIG. 4, an annealing process 308 is performed, in order to diffuse the nitrogen and the inert gas in the oxide layer 302. The annealing process 308 is performed at a temperature ranging from 700 Celsius degrees and 900 Celsius degrees. The annealing process 308 can be a rapid thermal annealing (RTA) step, a UV annealing step or a laser annealing step. Since a power of the DPN nitridation process 304 is less than a power of the plasma treatment 306, the inert gas would be placed in a position deeper than that of the nitrogen. Thus, after the annealing process 308, nitrogen will diffuse around a middle portion of the oxide layer to form layer 302N, the inert gas will diffuse around a lower portion of the oxide layer to form layer 302X. Since the inert gas has an atom size greater than nitrogen, it can avoid nitrogen from penetrating into the substrate 300.

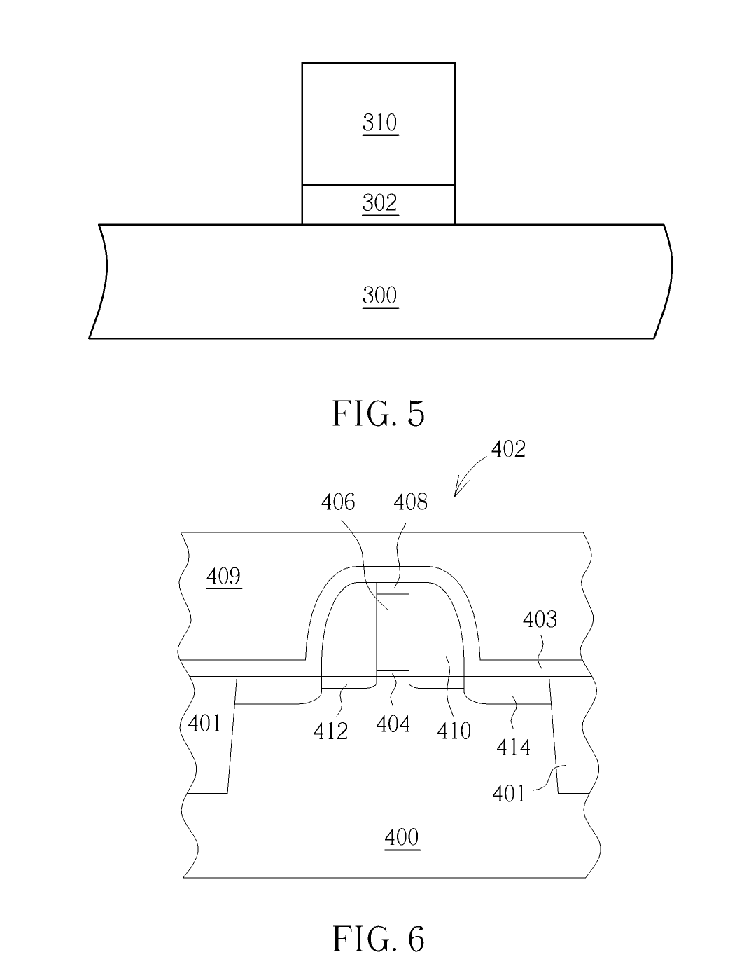

As shown in FIG. 5, a conductive layer 310 is formed on the oxide 302. In a more detail embodiment, a conductive material layer (not shown) is formed on the oxide layer 302 for directly covering the top surface of the oxide layer 302. The conductive material layer and the oxide layer 302 are patterned to form the conductive layer 310 and the patterned oxide layer 302. In one embodiment, the conductive layer 310 can be poly-silicon or a metal.

Other semiconductor manufacturing processes can still be performed to form various semiconductor devices. For example, after the step of FIG. 5, at least one implant process is performed to form a source/drain region (not shown) in the substrate 300 at two sides of the conductive layer 310. A transistor is therefore formed with the oxide layer 302 serving as the dielectric layer and the conductive layer 310 serving as the gate electrode. A high quality of channel region, which is located in the substrate 300 under the oxide layer 302, can be fabricated since no nitrogen is diffused into the substrate 300. It is noted that the above embodiment shows the planar transistor, but one skilled in the art can realized that the method of the present invention can also be used in non-planar transistor such as FinFET. The method proposed in the present invention can be used in any device that is suffering from nitrogen penetrating from an oxide layer into the under substrate.

Please refer to FIG. 6 to FIG. 10, which show schematic diagrams of forming a metal gate based on the method of forming a semiconductor device of the present invention. As shown in FIG. 6, a substrate 400 is provided, such as a silicon substrate, a silicon-containing substrate or a silicon-on-insulator substrate. A plurality of shallow trench isolations (STI) 401 is disposed on the substrate 400. A transistor 402 is formed on the substrate 400 encompassed by the STI 401, such as a PMOS or an NMOS.

In one embodiment shown in FIG. 6, the transistor 402 includes an interface layer 404, a sacrificial gate 406, a cap layer 408, a spacer 410, a lightly doped drain (LDD) 412 and a source/drain 414. In one preferred embodiment of the present invention, the interface layer 404 can be a SiO₂ layer. The sacrificial gate 406 is a poly-silicon gate. In another embodiment, the sacrificial gate 406 is a multi-layered gate including a poly-silicon layer, an amorphous silicon layer or a germanium layer. The cap layer 408 can be a SiN layer, for example. The spacer 410 can be a multi-layered structure including high temperature oxide (HTO), SiN, SiO or SiN formed by hexachlorodisilane (Si₂Cl₆) (HCD-SiN). The first LDD 412 and the first source/drain 414 are formed by appropriate dopants implantation. After forming the transistor 402, a contact etch stop layer (CESL) 403 and an inter-layer dielectric (ILD) layer 409 are formed on the substrate 400 to cover the transistor 402.

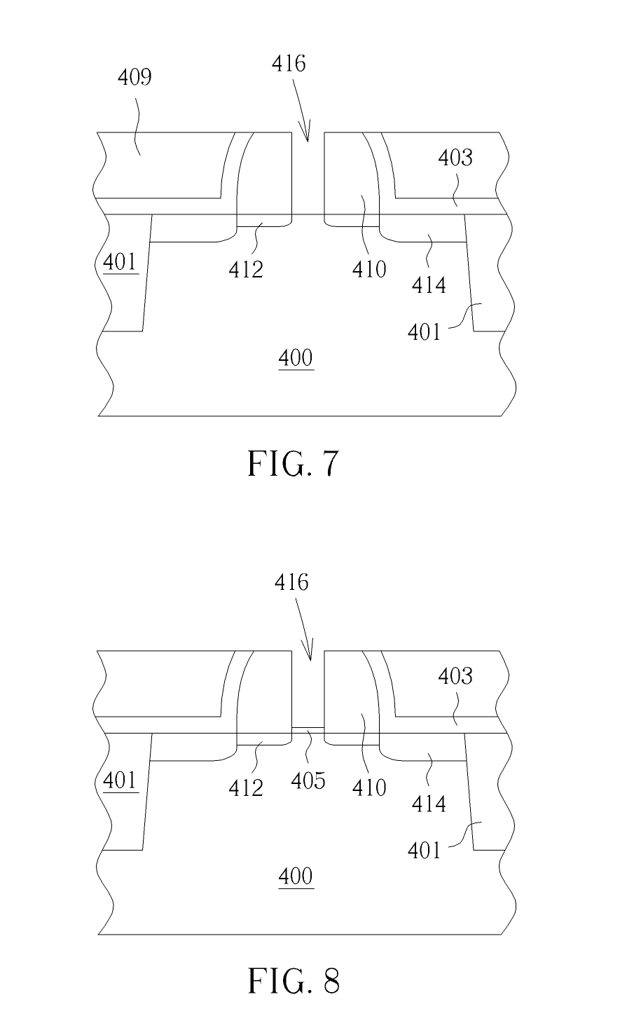

As shown in FIG. 7, a planarization process, such as a chemical mechanical polish (CMP) process, an etching-back process or a combination thereof is performed to remove a part of the ILD layer 409, a part of the CESL 403, a part of the spacer 410 and completely remove the cap layer 408, until the top surfaces of the sacrificial gate 406 are exposed. Thereafter, a wet etching process and/or a dry etching process is performed to remove the sacrificial gate 406 and the interfacial layer 404 until the substrate 400 is exposed. A trench 416 is formed in the transistor 402.

A shown in FIG. 8, an oxide layer 405 is formed at least on the exposed substrate 400 in the trench 416. In one embodiment, the oxide layer 405 is formed by a thermal oxidation process thus is formed only on a bottom portion of the trench 416. After forming the oxide layer 405, the nitridation process 404, the plasma treatment 306 and the annealing process 308 are carried out, as shown in FIG. 2, FIG. 3 and FIG. 4. For the sake of simplicity, detail descriptions of the nitridation process 404, the plasma treatment 306 and the annealing process 308 are omitted.

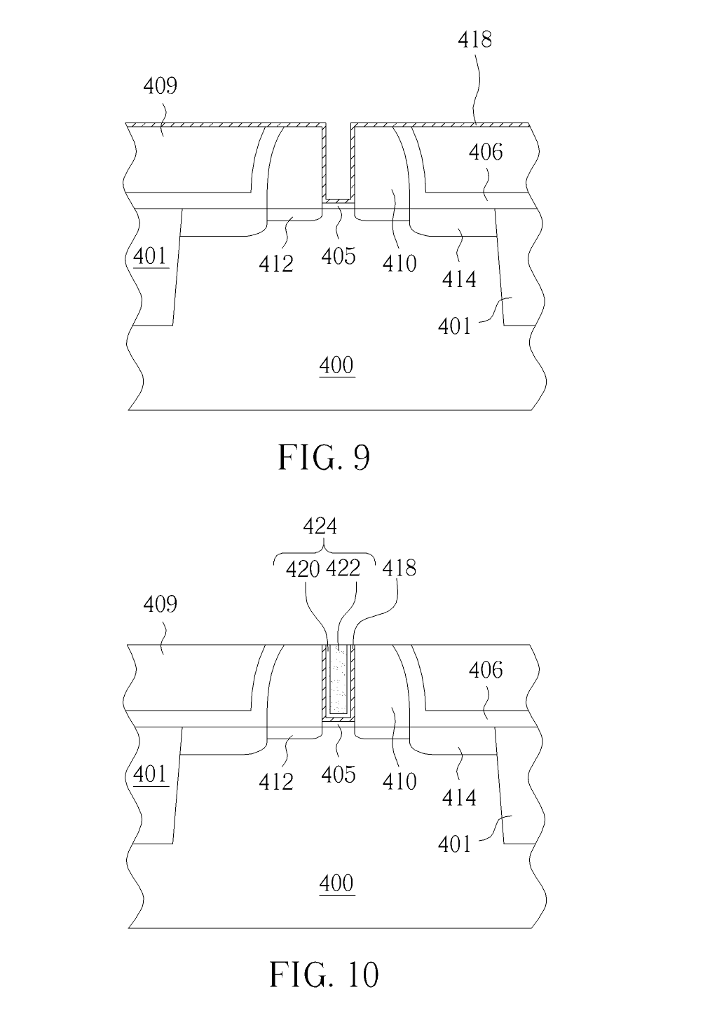

As shown in FIG. 9, an optional oxide layer 418 can be formed conformally in the trench 416 and on the oxide layer 405. The oxide layer 418 has a U shape in its cross section. In this embodiment, the oxide layer 418 can be SiO₂ or a high-k oxide layer, including rare earth metal oxides or lanthanide oxides, such as hafnium oxide (HfO₂), hafnium silicon oxide (HfSiO₄), hafnium silicon oxynitride (HfSiON), aluminum oxide (Al₂O₃), lanthanum oxide (La₂O₃), lanthanum aluminum oxide (LaAlO), tantalum oxide (Ta₂O₅), zirconium oxide (ZrO₂), zirconium silicon oxide (ZrSiO₄), hafnium zirconium oxide (HfZrO), yttrium oxide (Yb₂O₃), yttrium silicon oxide (YbSiO), zirconium aluminate (ZrAlO), hafnium aluminate (HfAlO), aluminum nitride (AlN), titanium oxide (TiO₂), zirconium oxynitride (ZrON), hafnium oxynitride (HfON), zirconium silicon oxynitride (ZrSiON), hafnium silicon oxynitride (HfSiON), strontium bismuth tantalite (SrBi₂Ta₂O₉, SBT), lead zirconate titanate (PbZrₓTi₁₋ₓO₃, PZT) or barium strontium titanate (BaₓSr₁₋ₓTiO₃, BST), but is not limited thereto.

In this embodiment, the nitridation process 404, the plasma treatment 306 and the annealing process 308 can be carried out for different oxide layers 405, 418. Preferably, the plasma treatment 306 is performed for the oxide layer 405, which is closest to the substrate 400, and the nitridation process 304 can be performed for the oxide layer 405 and/or the oxide layer 418. For example, the oxide layer 405 is subjected to the plasma treatment 306, and then the oxide layer 418 is subject to the nitridation process 304 and the annealing process 308. In another embodiment, the oxide layer 405 is subjected to the plasma treatment 306, the nitridation process 304 and after forming the oxide layer 418, the annealing process 308 is performed.

As shown in FIG. 9, after forming the oxide layer 405 (or the optional oxide layer 418), a work function metal layer 420 is formed on the substrate 400. The material of the work function metal layer 420 can be adjusted according to the type of the transistor 412. If the transistor 412 is a PMOS, the work function metal layer 420 includes Ni, Pd, Pt, Be, Ir, Te, Re, Ru, Rh, W, Mo, or WN, RuN, MoN, TiN, TaN, or WC, TaC, TiC, or TiAlN, TaAlN, but should not be limited thereto. If the transistor 412 is an NMOS, the work function metal layer 420 includes TiAl, ZrAl, WAl, TaAl or HfAl, but should not be limited thereto. In one embodiment, before forming the work function metal layer 420, a bottom barrier layer (not shown) can optionally be formed, such as a TaN layer. An optional top barrier layer (not shown) and a metal layer 422 can be formed on the substrate 400, wherein the trench 416 is completely filled by the metal layer 422. The metal layer contains Al, Ti, Ta, W, Nb, Mo, TiN, TiC, TaN, Ti/W or Ti/TiN and is not limited thereto.

Lastly, as shown in FIG. 10, a planarization process is carried out to remove the metal layer 422, the work function metal layer 420, and the oxide layer 418 outside the trench 416, so a metal gate 424 including the metal layer 422 and the work function metal 420 is therefore formed. Since the plasma treatment 306 is provided for the oxide layer 405 and/or the oxide layer 418, the possibility of nitrogen penetrating into the substrate 300 can be therefore reduced.

In light of above, the present invention provides a method of forming a semiconductor device that might encounter the problem of nitrogen penetrating from an oxide layer into the under substrate. The present invention utilizes a plasma treatment with inert gas to avoid this problem, so as to upgrade the device performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor device, comprising:
providing a substrate having an exposed oxide layer;
performing a nitridation process for the oxide layer;
after the nitridation process, performing a plasma treatment containing an inert gas for the oxide layer; and
forming a conductive layer on the oxide layer.

2. The method of forming a semiconductor device according to claim 1, wherein the conductive layer directly contacts the oxide layer.

3. The method of forming a semiconductor device according to claim 1, wherein the inert gas comprises Xe, Kr or Ra.

4. The method of forming a semiconductor device according to claim 1, wherein the nitridation process includes a decoupled plasma nitridation (DPN) process.

5. The method of forming a semiconductor device according to claim 4, wherein a power of the DPN process is substantially less than a power of the plasma treatment.

6. The method of forming a semiconductor device according to claim 4, wherein a gas flow rate of the nitride is substantially less than a gas flow rate of the inert gas.

7. The method of forming a semiconductor device according to claim 1, wherein the plasma treatment only supplies the inert gas.

8. The method of forming a semiconductor device according to claim 1, wherein the oxide layer is formed by a thermal oxidation process.

9. The method of forming a semiconductor device according to claim 1, wherein the conductive layer comprises poly-silicon or metal.

10. The method of forming a semiconductor device according to claim 1, wherein the semiconductor device is a transistor and the oxide layer serves as gate dielectric of the transistor and the conductive layer serves as gate of the transistor.

11. A method of forming a semiconductor device, comprising:
providing a substrate;
forming a first oxide layer on the substrate;
after forming the first oxide layer, performing a plasma treatment containing an inert gas;
after the plasma treatment, forming a second oxide layer on the first oxide layer;
after forming the first oxide layer, performing a nitridation process; and
forming a conductive layer on the second oxide layer.

12. The method of forming a semiconductor device according to claim 11, wherein the first oxide layer directly contacts the second oxide layer.

13. The method of forming a semiconductor device according to claim 11, wherein the inert gas comprises Xe, Kr or Ra.

14. The method of forming a semiconductor device according to claim 11, wherein the nitridation process is performed before forming the second oxide layer.

15. The method of forming a semiconductor device according to claim 11, wherein the nitridation process is performed after forming the second oxide layer.

16. The method of forming a semiconductor device according to claim 11, further comprising performing an annealing process after the nitridation process.

17. The method of forming a semiconductor device according to claim 11, wherein the nitridation process includes a decoupled plasma nitridation (DPN) process.

18. The method of forming a semiconductor device according to claim 11, wherein the first oxide layer comprises SiO₂ and the second oxide layer comprises a high-k oxide layer.

19. The method of forming a semiconductor device according to claim 11, wherein the conductive layer comprises poly-silicon or metal.

20. The method of forming a semiconductor device according to claim 11, wherein the semiconductor device is a transistor and the first oxide layer serves as interfacial layer of the transistor, the second oxide layer serves as gate dielectric layer of the transistor and the conductive layer serves as gate of the transistor.
